(19) United States
(12) Patent Application Publication
(10) Pub. No.: US 2014/0103416 A1
(43) Pub. Date: Apr. 17, 2014

(54) SEMICONDUCTOR DEVICE HAVING ESD PROTECTION STRUCTURE AND ASSOCIATED METHOD FOR MANUFACTURING

(71) Applicant: Chengdu Monolithic Power Systems Co., Ltd., Chengdu (CN)

(72) Inventors: Rongyao Ma, Chengdu (CN); Tiesheng Li, San Jose, CA (US); Huaifeng Wang, Chengdu (CN); Heng Li, Chengdu (CN); Fayou Yin, Chengdu (CN)

(73) Assignee: CHENGDU MONOLITHIC POWER SYSTEMS CO., LTD., Chengdu (CN)

(21) Appl. No.: 14/051,342

(22) Filed: Oct. 10, 2013

(30) Foreign Application Priority Data
Oct. 12, 2012 (CN) 201210385427.9

(51) Int. Cl. H01L 29/78; H01L 29/66

(52) U.S. Cl. CPC H01L 29/7801; H01L 29/66674
USPC 257/316; 438/257

(57) ABSTRACT

A semiconductor device having an ESD protection structure and a method for forming the semiconductor device. The semiconductor device further includes a semiconductor transistor formed in an active cell area of a substrate. The ESD protection structure is formed atop a termination area of the substrate and is of solid closed shape. The ESD protection structure includes a central doped zone of a first conductivity type and a plurality of second-conductivity-type doped zones and first-conductivity-type doped zones alternately disposed surrounding the central doped zone. The central doped zone occupies substantially the entire portion of the ESD protection structure that is overlapped by a gate metal pad, and is electrically coupled to the gate metal pad. The outmost first-conductivity-type doped zone is electrically coupled to a source metal. The ESD protection structure features a reduced resistance and an improved current uniformity and provides enhanced ESD protection to the transistor.

### CROSS-REFERENCE TO RELATED APPLICATION(S)

This application claims the benefit of CN application No. 201210385427.9 filed on Oct. 12, 2012 and incorporated herein by reference.

### TECHNICAL FIELD

This disclosure relates generally to semiconductor devices, and more particularly but not exclusively relates to semiconductor devices having an ESD protection structure.

### BACKGROUND

Semiconductor devices, such as metal oxide semiconductor field effect transistors (“MOSFETs”), junction field effect transistors (“JFETs”), and double diffused metal-oxide semiconductor (DMOS) transistors etc. are widely used in various electronic products. To name a few examples, these semiconductor devices may be used in power amplifiers and low noise amplifiers in communication applications, and may also be used as switching elements of power converters in power management applications. For improving the operation stability and device ruggedness of such kind of semiconductor devices, electro-static discharge (“ESD”) protection structures are generally provided.

For instance, when a DMOS transistor functions as a power switch of a power converter, the DMOS transistor may suffer, between its gate region/electrode and its source region/electrode, a gate to source voltage as high as over 10,000 volts caused by ESD when the DMOS transistor changes to its off state instantly. Such a high gate to source voltage due to the ESD can damage a gate oxide of the DMOS transistor instantly, resulting in the power converter employing the DMOS transistor malfunctioning. Generally, to protect the gate oxide of the DMOS transistor from being damaged, an ESD protection module is coupled between the gate and source of the DMOS transistor. The ESD protection module is configured to provide a conduction path between the source and the gate of the DMOS transistor, so as to discharge the large extra energy due to ESD, when the gate to source voltage of the DMOS transistor exceeds an ESD threshold voltage of the ESD protection module. The ESD protection module can be a discrete module or can be integrated into the DMOS transistor. Integrating the ESD protection module with the semiconductor transistor that it is intended to protect tends to be the main trend for reducing the size and manufacturing cost of the semiconductor device.

Typically, the ESD protection module may comprise a group of PN diodes. In a semiconductor device comprising the ESD protection module integrated with a semiconductor transistor, the group of PN diodes of the ESD protection module may be formed by depositing a polysilicon layer atop a substrate where the semiconductor transistor such as a MOSFET is formed in, and subsequently doping the polysilicon layer with P type and N type dopants so as to form a group of alternately arranged P type doped regions and N type doped regions. The group of PN diodes (formed by the alternately arranged P type doped regions and N type doped regions) is electrically coupled between a source metal electrode and a gate metal electrode of the semiconductor transistor to protect the gate oxide of the semiconductor transistor. However, the group of PN diodes may have a series resistance which is one of the factors that affects the protection performance of the ESD protection module. Another factor includes the current uniformity (i.e. the capability of distributing a current flowing through the PN diodes uniformly) of the PN diodes. The protection performance of the ESD protection module improves according to decrease in resistance and increase in current uniformity of the PN diodes.

A need therefore exists for a semiconductor device having an integrated ESD protection structure that features a small resistance and a good current uniformity.

### SUMMARY

In accomplishing the above and other objects, there has been provided, in accordance with an embodiment of the present disclosure, a semiconductor device. The semiconductor device comprises: a semiconductor substrate of a first conductivity type and having an active cell area and a termination area, a semiconductor transistor formed in the active cell area, and an ESD protection structure formed atop the termination area of the semiconductor substrate. In one embodiment, the semiconductor transistor has a drain region, a gate region, and a source region. The ESD protection structure comprises a first insulation layer and an ESD protection layer, wherein the first insulation layer is disposed between the ESD protection layer and the substrate to isolate the ESD protection layer from the substrate. In one embodiment, the semiconductor device further comprises a source metal formed over the active cell area of the substrate and electrically coupled to the source region, and a gate metal formed over the termination area of the substrate and electrically coupled to the gate region, wherein the gate metal includes a gate metal pad and a gate metal runner, and wherein the gate metal is formed around outside of the source metal and is separated from the source metal with a gap. In one embodiment, the ESD protection layer of the ESD protection structure has a solid closed shape and includes a central doped zone of the first conductivity type located in a central portion of the ESD protection layer, and a plurality of second-conductivity-type doped zones and first-conductivity-type doped zones arranged alternately surrounding the central doped zone towards an outer portion of the ESD protection layer, wherein the second conductivity type is opposite to the first conductivity type, and wherein the central doped zone is located underneath the gate metal pad and occupies substantially the entire central portion of the ESD protection layer that is overlapped by the gate metal pad, and wherein the central doped zone is electrically coupled to the gate metal pad and the outmost first-conductivity-type doped zone among the plurality of second-conductivity-type doped zones and first-conductivity-type doped zones is electrically coupled to the source metal.

There has been further provided, in accordance with an embodiment of the present disclosure, a method for forming a semiconductor device having a semiconductor transistor and an ESD protection structure. The method comprises: providing a semiconductor substrate having a first conductivity type, wherein the substrate includes an active cell area and a termination area that are respectively designated for forming active cells of the semiconductor transistor and the ESD protection structure; forming the semiconductor transistor in the active cell area; forming the ESD protection structure atop a top surface of the substrate over the termination area; forming a source metal over the active cell area of the substrate; and forming a gate metal over the termination area of the substrate around outside of the source metal and separated from the source metal with a gap, wherein the gate metal includes a gate metal pad and a gate metal runner. In one embodiment, forming the semiconductor transistor comprises forming a drain region, a gate region and a source region. In one embodiment, forming the ESD protection structure comprises: forming a first insulation layer atop the top surface of the substrate over the termination area; forming an ESD protection layer of a solid closed shape atop the first insulation layer; and doping the ESD protection layer so that the ESD protection layer includes a central doped zone of the first conductivity type and a plurality of second-conductivity-type doped zones and first-conductivity-type doped zones alternately arranged surrounding the central doped zone towards an outer portion of the ESD protection layer wherein the second conductivity type is opposite to the first conductivity type. In one embodiment, the gate metal pad is formed directly over the central doped zone of the ESD protection layer and the central doped zone occupies substantially the entirety of the portion of the ESD protection layer overlapped by the gate metal pad. In one embodiment, the method further comprises coupling the gate metal pad to the central doped zone, and coupling the source metal to the outermost first-conductivity-type doped zone among the plurality of second-conductivity-type doped zones and first-conductivity-type doped zones.

There has been further provided, in accordance with an embodiment of the present disclosure, a method for forming a semiconductor device having an ESD protection structure. The method comprises the following steps: a) providing a semiconductor substrate having a first conductivity type, wherein the substrate includes an active cell area and a termination area that are respectively designated for forming active cells of a semiconductor transistor and the ESD protection structure; b) forming a gate region in the active cell area; c) forming a body implantation layer of a second conductivity type near top surface of the substrate, wherein the second conductivity type is opposite to the first conductivity type; d) forming a first insulation layer atop the substrate; e) forming an ESD polysilicon layer atop the first insulation layer; f) forming an ESD implantation layer of the second conductivity type near top surface of the ESD polysilicon layer; g) diffusing the body implantation layer substantially evenly to a desired depth in the substrate to form a body region, and diffusing the ESD implantation layer substantially evenly to the entire ESD protection layer so that the ESD protection layer have the second conductivity type; h) patterning the ESD polysilicon layer and the first insulation layer so that a remained portion of the ESD protection layer and an underlying remained portion of the first insulation layer are located atop the termination area of the substrate and are of solid closed shape; i) doping the substrate and the ESD polysilicon layer with dopants of the first conductivity type under the shield of a patterned source implantation mask layer so that source regions of the first conductivity type are formed and laterally located on both sides of the gate region in the body region, and that the ESD polysilicon layer includes a central doped zone of the first conductivity type and a plurality of second-conductivity-type doped zones and first-conductivity-type doped zones alternately arranged surrounding the central doped zone towards an outer portion of the ESD polysilicon layer; and j) forming a source metal over the active cell area of the substrate, and forming a gate metal over the termination area of the substrate around outside of the source metal and separated from the source metal with a gap; wherein the gate metal includes a gate metal pad and a gate metal runner; and wherein the gate metal pad is directly over the central doped zone of the ESD polysilicon layer and the central doped zone occupies substantially the entirety of the portion of the ESD polysilicon layer overlapped by the gate metal pad; and wherein the gate metal pad is electrically coupled to the central doped zone, and the source metal is electrically coupled to the outermost first-conductivity-type doped zone among the plurality of second-conductivity-type doped zones and first-conductivity-type doped zones.

In one embodiment, the step c) of body implantation is omitted, and wherein the step h) is proceeded prior to the step f) so that the body implantation layer is formed in step f) at the same time with forming the ESD implantation layer, wherein the body implantation layer formed in step f) locates in portions of the substrate that are uncovered by the closed shape ESD polysilicon layer and first insulation layer.

### BRIEF DESCRIPTION OF THE DRAWINGS

The following detailed description of various embodiments of the present invention can best be understood when read in conjunction with the following drawings, in which the features are not necessarily drawn to scale but rather are drawn as to best illustrate the pertinent features.

FIG. 1 illustrates a cross-sectional view of a semiconductor device 100 in accordance with an exemplary embodiment of the present invention.

FIG. 2 illustrates a top plan view of the semiconductor device 100 in accordance with an exemplary embodiment of the present invention.

FIG. 3 illustrates a top plan view illustrating a plan arrangement of the ESD protection layer 109 in accordance with an exemplary embodiment of the present invention.

FIG. 4 illustrates a partial enlarged top plan view of an area near the gate metal pad 107₁ corresponding to the top plan view of FIG. 2 in accordance with an exemplary embodiment of the present invention.

FIGS. 5A-5I are cross-sectional views illustrating schematically a sequential process of a method for forming a semiconductor device having an ESD protection structure in accordance with an embodiment of the present invention.

FIGS. 6A-6H are cross-sectional views illustrating schematically a sequential process of a method for forming a semiconductor device having an ESD protection structure in accordance with an alternative embodiment of the present invention.

The use of the same reference label in different drawings indicates the same or like components or structures with substantially the same functions for the sake of simplicity.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the terms “left,” “right,” “in,” “out,” “front,” “back,” “up,” “down”, “top,” “atop”, “bottom,” “over,” “under,” “above,” “below” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The term “coupled,” as used herein, is defined as directly or indirectly connected in an electrical or non-electrical manner. The terms “a,” “an,” and “the” includes plural reference, and the term “in” includes “in” and “on”. The phrase “in one embodiment,” as used herein does not necessarily refer to the same embodiment, although it may. The term “or” is an inclusive “or” operator, and is equivalent to the term “and/or” herein, unless the context clearly dictates otherwise. Where either a field effect transistor (“FET”) or a bipolar junction transistor (“BJT”) may be employed as an embodiment of a transistor, the scope of the words “gate”, “drain”, and “source” includes “base”, “collector”, and “emitter”, respectively, and vice versa. The symbols “+” and “−” when used to describe dopants or doped regions/zones are merely used to descriptively indicate relative dopant concentration levels, but not intend to specify or limit the dopant concentration ranges, nor intend to add other limitations to the dopants and doped regions/zones. For instance, both “N⁺ type” and “N⁻ type” can be referred to as “N type” in more general terms, and both “P⁺ type” and “P⁻ type” can be referred to as “P type” in more general terms. Those skilled in the art should understand that the meanings of the terms identified above do not necessarily limit the terms, but merely provide illustrative examples for the terms.

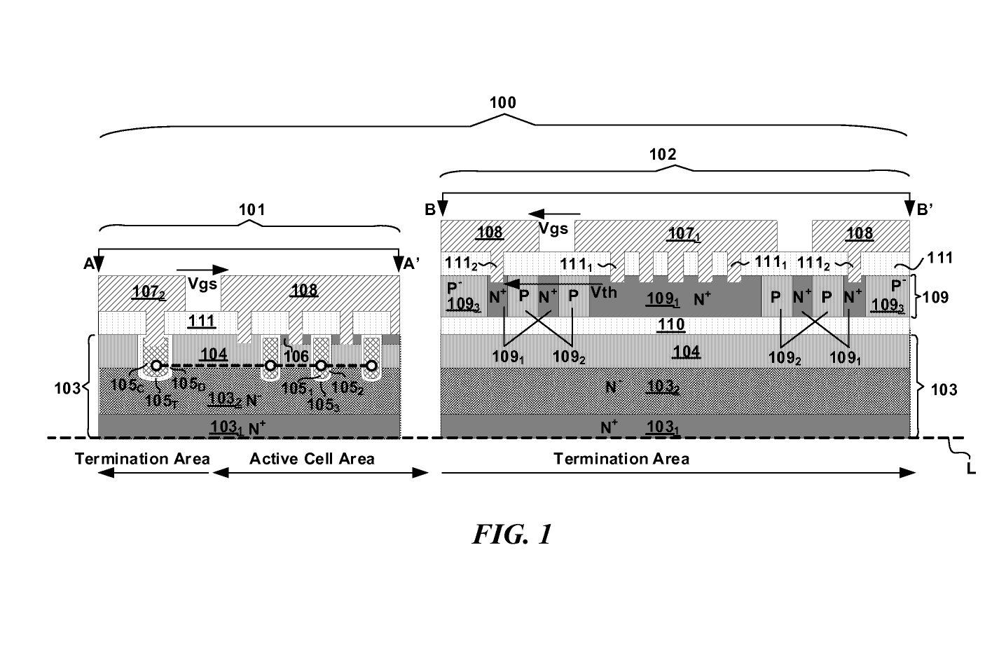

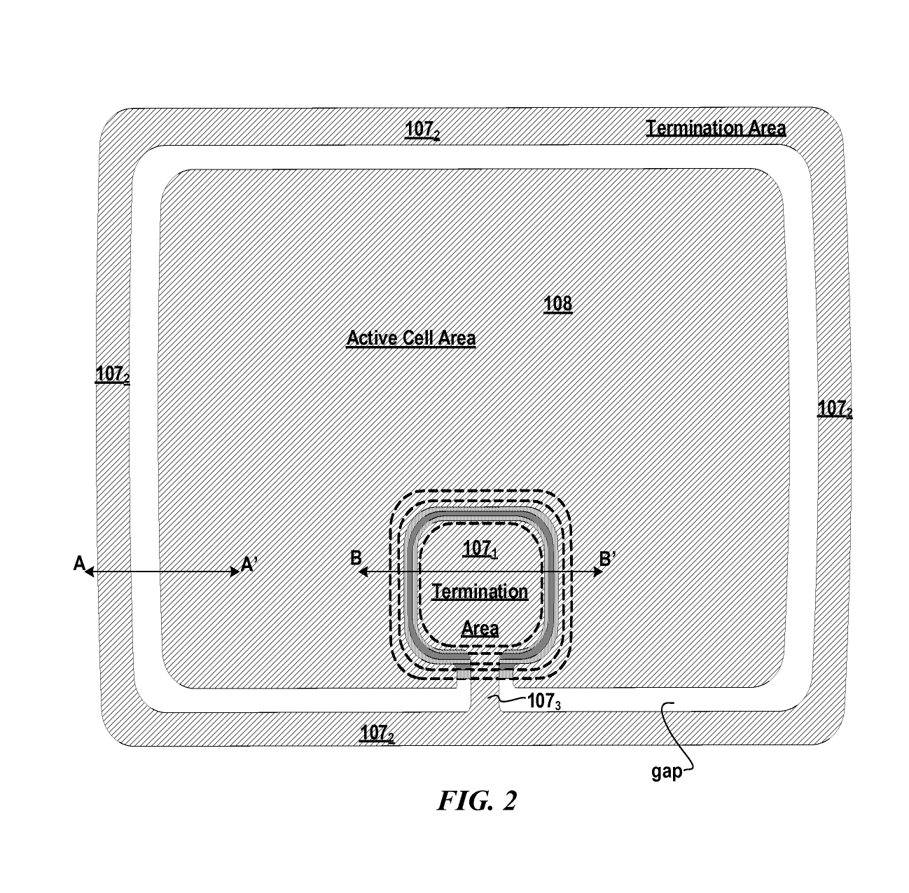

FIG. 1 illustrates a cross-sectional view of a semiconductor device 100 in accordance with an exemplary embodiment of the present invention. FIG. 2 illustrates a top plan view of the semiconductor device 100 in accordance with an exemplary embodiment of the present invention. In accordance with an embodiment of the present invention, the semiconductor device 100 may comprise a semiconductor transistor 101 (e.g. illustrated in FIG. 1 as a MOSFET at the left side of the device 100) and an electro-static discharge (“ESD”) protection structure 102 (e.g. illustrated in FIG. 1 at the right side of the device 100). It should be noted that FIG. 2 illustrates a top plan view of the whole die of semiconductor device 100 with only the metal layer and polysilicon layer of the ESD protection structure 102 shown, while FIG. 1 illustrates a cross-sectional view of only portions of the semiconductor device 100. For example, it can be understood that the left side sectional view and the right side sectional view illustrated in FIG. 1 respectively correspond to the portions cut from the cut lines AA′ and BB′ in FIG. 2. However, it should also be understood that the corresponding relationship between the cross-sectional view and the top plan view of the semiconductor device 100 illustrated in FIG. 1 and FIG. 2 are not intended to be limiting.

In the exemplary embodiment shown in FIG. 1, the semiconductor device 100 has a substrate 103 of a first conductivity type (e.g. illustrated as N type in FIG. 1). The substrate 103 may comprise a relatively heavy doped substrate layer 103₁ (e.g. illustrated as an N⁺ substrate layer in FIG. 1) and a relatively light doped epitaxial layer 103₂ (e.g. illustrated as an N⁻ epitaxial layer in FIG. 1) formed on the substrate layer 103₁. That is to say, the substrate layer 103₁ has a larger dopant concentration than the epitaxial layer 103₂. The substrate 103 may have an active cell area and a termination area (also referring to FIG. 2). In an embodiment, the semiconductor transistor 101 is formed in the active cell area and the ESD protection structure 102 is formed in the termination area.

In accordance with an embodiment of the present invention, the semiconductor transistor 101 may comprise a drain region (103), a gate region 105, and a source region 106. In the example of FIG. 1, the heavy doped substrate layer 103₁ functions as the drain region of the semiconductor transistor 101, and the light doped epitaxial layer 103₂ functions as a drift region. In accordance with an embodiment of the present invention, the semiconductor device 100 may further comprise a gate metal 107 electrically coupled to the gate region 105, and a source metal 108 electrically coupled to the source region 106.

In accordance with an embodiment of the present invention, the semiconductor transistor 101 may further comprise a body region 104 formed on the substrate 103 having a second conductivity type (e.g. illustrated as P type in FIG. 1) opposite to the first conductivity type. The body region 104 may be formed through second-conductivity-type dopant implantation in the substrate 103 (from the top surface of the epitaxial layer 103₂). The body region 104 may have a relatively light dopant concentration.

In the exemplary embodiment shown in FIG. 1, the gate region 105 for semiconductor transistor 101 is illustrated as a trenched gate region, comprising a trenched gate 105₁ and a gate dielectric layer 105₂ formed in a gate trench 105₃. The gate trench 105₃ is formed in the substrate 103, extends vertically from the top surface of the substrate 103 through the body region 104 into the epitaxial layer 103₂. The gate dielectric layer 105₂ lines the sidewalls and the bottom of the gate trench 105₃, and the trenched gate 105₁ fills the lined trench 105₃ and is thus isolated from the substrate 103 and the body region 104 by the gate dielectric layer 105₂. In the example of FIG. 1, a plurality of trenched gate regions 105 are shown, the plurality of trenched gate regions 105 illustrated in sectional view are actually electrically connected with each other by transverse segments (illustrated in FIG. 1 by dotted line) of the trenched gate regions 105 having the same structure as those shown in the sectional view. According to the exemplary embodiment shown in FIG. 1, the source region 106 is formed adjacent to the gate region 105, for instance, located laterally at both sides (left side/a first side and right side/a second side opposite to the first side) of the gate trench 105₃. The source region 106 is of the first conductivity type and may have a relatively heavy dopant concentration (e.g. illustrated as an N⁺ source region in FIG. 1). According to an embodiment of the present invention, the trenched gate region 105 is electrically coupled to the gate metal 107 via a trenched gate contact comprising a contact conduction layer 105_{C} and a contact dielectric layer 105_{D} formed in a contact trench 105_{T}. The trenched gate contact has a trench width greater than the trenched gate region 105 to facilitate the connection between the contact conduction layer 105_{C} and the gate metal 107 so as to couple the gate region 105 to the gate metal 107. In one embodiment, the gate trenches 105₃ and the gate contact trenches 105_{T} are connected by a transverse segment (illustrated in FIG. 1 by dotted line) of either the gate trenches 105₃ or the gate contact trenches 105_{T} such that the trenched gate 105₁ are connected to the contact conduction layer 105_{C}. Similarly as the trenched gate region 105, the contact dielectric layer 105_{D} lines the sidewalls and the bottom of the contact trench 105_{T}, and the contact conduction layer 105_{C} fills the lined trench 105_{T} and is thus isolated from the substrate 103 and the body region 104 by the contact dielectric layer 105_{D}. In one embodiment, the contact conduction layer 105_{C} and the trenched gate 105₁ may comprise a same conduction material such as doped polysilicon. In other embodiments, the contact conduction layer 105_{C} and the trenched gate 105₁ may comprise different conduction materials. In one embodiment, the contact dielectric layer 105_{D} and the gate dielectric layer 105₂ may comprise a same dielectric material such as silicon dioxide. In other embodiments, the contact dielectric layer 105_{D} and the gate dielectric layer 105₂ may comprise different dielectric materials. In FIG. 1, the gate contact trenches 105_{T} and the gate trenches 105₃ are illustrated to have a depth substantially the same, while in other embodiment the depth of gate contact trenches 105_{T} may not match that of the gate trenches 105₃. In the present disclosure, the term “laterally” refers to the direction parallel to the cut line L of the bottom surface of the substrate 103. The term “width” refers to a distance measured laterally. The term “vertically” refers to the direction perpendicular to the bottom surface of the substrate 103. The term “depth” refers to a distance measured vertically. One having ordinary skill in the art should understand that the structures and connections of the gate regions 105 and the trenched gate contacts including the contact trench 105_{T}, the contact conduction layer 105_{C} and the contact dielectric layer 105_{D} shown in FIG. 1 are only for purpose of illustration. Actually, the structures, arrangements, and connection relationships of the gate regions 105 and the trenched gate contacts are not limited to that shown in FIG. 1 and that described above with reference to FIG. 1.

In accordance with an embodiment of the present invention, still referring to FIG. 1 and FIG. 2, the source metal 108 and the gate metal 107 are respectively formed over the active cell area and the termination area of the substrate 103, with a gap therebetween to separate the gate metal 107 from the source metal 108. The gate metal 107 may comprise a gate metal pad 107₁ and a gate metal runner 107₂. In the example illustrated in FIG. 2, the gate metal 107 is formed around outside of the source metal 108 and surrounds the source metal 108. In other embodiments, the gate metal 107 may not necessarily totally surrounds the source metal 108.

In accordance with an embodiment of the present invention, the ESD protection structure 102 may comprise an ESD protection layer 109 disposed over the termination area of the substrate 103, and a first insulation layer 110 disposed between the ESD protection layer 109 and the substrate 103 to isolate the ESD protection layer 109 from the substrate 103. In accordance with an embodiment of the present invention, the ESD protection layer 109 may comprise a doped polysilicon layer, having a plurality of alternately disposed first-conductivity-type doped zones 109₁ (e.g. illustrated in FIG. 1 as N⁺ type doped zones) and second-conductivity-type doped zones 109₂ (e.g. illustrated in FIG. 1 as P type doped zones), i.e. the plurality of first-conductivity-type doped zones 109₁ and the plurality of second-conductivity-type doped zones 109₂ are interleaved with each other. For instance, in the example shown in FIG. 1 and FIG. 2, the plurality of alternately disposed first-conductivity-type doped zones 109₁ and second-conductivity-type doped zones 109₂ are illustrated as a plurality of alternately disposed N⁺ type and P type zones having an arrangement N⁺-P-N⁺-P-N⁺ from an inner side to an outer side of the ESD protection layer 109. In other alternative embodiments of the present invention, the ESD protection layer 109 may be formed of other conductive or semi-conductive materials other than polysilicon that are compatible with other aspects of the device manufacturing process. Thus, the term “poly-silicon” is intended to include such other conductive or semi-conductive materials and combinations thereof in addition to silicon.

In accordance with an embodiment of the present invention, the ESD protection layer 109 may have a solid closed shape. The closed shape ESD protection layer 109 may include a central doped zone 109₁ of the first conductivity type (e.g. illustrated in FIG. 1 as an N⁺ type doped zone) located in a central portion of the ESD protection layer 109, and a plurality of second-conductivity-type doped zones 109₂ (e.g. illustrated in FIG. 1 as P type doped zones) and first-conductivity-type doped zones 109₁ (e.g. illustrated in FIG. 1 as N⁺ type doped zones) arranged alternately surrounding the central doped zone 109₁ towards an outer portion of the ESD protection layer 109. To provide an illustrative example, referring to FIG. 1, the closed shaped ESD protection layer 109 is illustrated to include an N⁺ type central doped zone 109₁ and a plurality of alternately disposed P type (109₂) and N⁺ type (109₁) doped zones having an arrangement P-N⁺-P-N⁺ surrounding the N⁺ type central doped zone 109₁. In accordance with an embodiment of the present invention, the first-conductivity-type central doped zone 109₁ is located underneath the gate metal pad 107₁ and occupies substantially the entire portion of the ESD protection layer 109 that is directly underneath the gate metal pad 107₁. That is to say, the central portion of the ESD protection layer 109 holding the central doped zone 109₁ refers substantially to the entire portion that is overlapped by the gate metal pad 107₁. According to this exemplary embodiment, the ESD protection structure 102 actually comprises a plurality of PN diodes connected in series that are formed by the plurality of alternately disposed first-conductivity-type doped zones 109₁ (including the central doped zone 109₁) and second-conductivity-type doped zones 109₂ in the ESD protection layer 109. In accordance with an embodiment of the present invention, the central doped zone 109₁ is electrically coupled to the gate metal pad 107₁, the outermost first-conductivity-type doped zone 109₁ (which is located furthest to the central doped zone 109₁) among the plurality of alternately arranged second-conductivity-type doped zones 109₂ and first-conductivity-type doped zones 109₁ surrounding the central doped zone 109₁ is electrically coupled to the source metal 108. Therefore, the ESD protection structure 102 (i.e. the plurality of PN diodes in the ESD protection layer) is electrically coupled between the gate metal 107 (or the gate region 105) and the source metal 108 (or the source region 106) of the semiconductor transistor 101 (e.g. MOSFET in FIG. 1). In accordance with an embodiment of the present invention, when a gate-to-source voltage Vgs caused by electro-static discharge presents between the gate region 105 and the source region 106 of the semiconductor transistor 101 and exceeds an ESD threshold voltage Vth of the ESD protection structure 102, the series connected PN diodes are turned on (i.e. the ESD protection structure 102 is turned on) to provide a current conduction path between the gate region 105 and the source region 106 of the semiconductor transistor 101 so as to protect the gate dielectric layer 105₂ of the gate region 105 from being damaged. The ESD threshold voltage Vth can be modified by modifying the number of the plurality of alternately disposed second-conductivity-type doped zones 109₂ and first-conductivity-type doped zones 109₁ surrounding the central doped zone 109₁. Consequently, the term “plurality of” herein is not exclusively limited to more than one, but is intended to include one.

In accordance with an embodiment of the present invention, the first-conductivity-type central doped zone 109₁ and the other first-conductivity-type doped zones 109₁ may have a relatively heavy dopant concentration (e.g. higher than 1×10¹⁹ cm⁻³ and illustrated by N⁺ in FIG. 1) compared to the plurality of second-conductivity-type doped zones 109₂ to reduce a series resistance of the ESD protection structure 102 (i.e. the series resistance of the PN diodes formed in the ESD protection layer 109) and to improve a current uniformity of the ESD protection structure 102. In one embodiment, the relatively heavy dopant concentration of the first-conductivity-type doped zones 109₁ may be the same as that of the source region 106. The second-conductivity-type doped zones 109₂ may have a relatively light dopant concentration (e.g. illustrated by P in FIG. 1) compared to the first-conductivity-type doped zones 109₁ to support higher gate to source voltage Vgs. In one embodiment, the relatively light dopant concentration of the second-conductivity-type doped zones 109₂ may be the same as that of the body region 104. In addition, in an exemplary embodiment, since the central doped zone 109₁ occupies substantially the entire portion of the ESD protection layer 109 that is overlapped by the gate metal pad 107₁ (i.e. a top plan view surface area of the central doped zone 109₁ is substantially as large as that of the gate metal pad 107₁), the series resistance of the ESD protection structure 102 is further reduced and the current uniformity of the ESD protection structure 102 is enhanced. In the meanwhile, since the overlapped surface area between the central doped zone 109₁ and the gate metal pad 107₁ is made as large as possible, which renders a larger contactable surface area (i.e. the allowable surface area for forming connections) between the central doped zone 109₁ and the gate metal pad 107₁, a contact resistance between the gate metal 107 and the ESD protection structure 102 may be beneficially reduced.

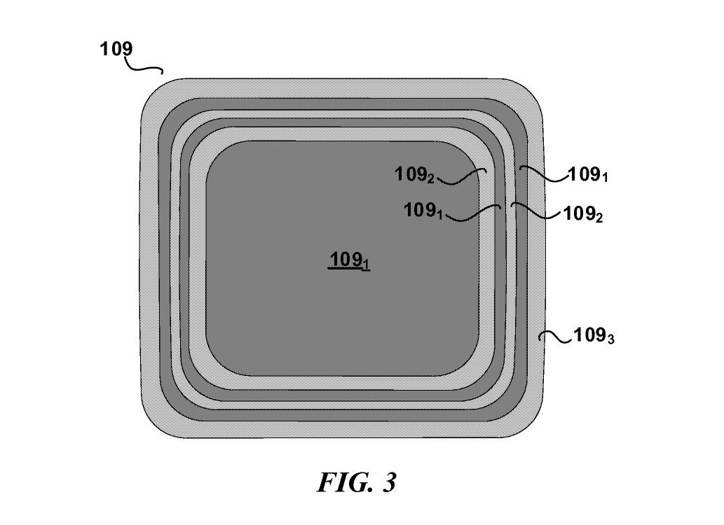

FIG. 3 illustrates a top plan view illustrating a plan arrangement of the ESD protection layer 109 in accordance with an exemplary embodiment of the present invention. In FIG. 3, the solid closed shape ESD protection layer 109 is illustrated in round rectangle shape. However, those having ordinary skill in the art should understand that the ESD protection layer 109 is not limited to have round rectangle shape, but can have any other closed-shape, such as round circular shape, elliptic shape, round polygonal shape etc. Therefore, the term “solid closed shape” in the present disclosure is only descriptive but not exclusive, and is intended to include any solid and flat closed-shape.

In accordance with an embodiment of the present invention, the ESD protection layer 109 may further have a floating doped zone 109₃ having the second conductivity type and formed surrounding and next to the outermost first-conductivity-type doped zone 109₁. The floating doped zone 109₃ may have a relatively light dopant concentration, for instance, as light as or lighter than that of the plurality of second-conductivity-type doped zones 109₂. As an example, the floating doped zone 109₃ in the embodiment of FIG. 1 is illustrated as a P⁻ type doped zone having lighter dopant concentration than the P type doped zones 109₂. However, this is not intended to be limiting. The floating doped zone 109₃ is not intended to couple any established potentials (e.g. the floating doped zone 109₃ is not coupled to any of the source electrode/source metal 108, gate electrode/gate metal 107 and drain electrode of the semiconductor transistor 101), but is electrically floating and has a floating potential. The floating doped zone 109₃ forms a potential barrier to the free carries (e.g. to free electrons in the examples of FIGS. 1-3) outside the ESD protection layer 109 to block leakage current/carriers go through so as to shield the ESD protection structure 102 from being influenced by outside free carriers. It works similarly as a junction-isolation to protect the core ESD protection structure formed e.g. by the plurality of alternately disposed first-conductivity-type doped zones 109₁ and second-conductivity-type doped zones 109₂ inside the floating doped zone 109₃. Therefore, the safety and ESD current handling performance of the ESD protection structure 102 can be further improved.

In accordance with an embodiment of the present invention, the semiconductor device 100 may further comprise an interlayer dielectric (“ILD”) layer 111 that is disposed between the metal layer (e.g. including the source metal 108 and gate metal 107) and the ESD protection layer 109 and the substrate 103 to prevent the source metal 108 being undesirably shorted to the gate region 105 and/or the gate metal 107 being undesirably shorted to the source region 106. In accordance with an embodiment of the present invention, the central doped zone 109₁ of the ESD protection layer 109 is electrically coupled to the overlying gate metal pad 107₁ through a first plurality of vias 111₁ formed in the ILD layer 111. Similarly, the outermost first-conductivity-type doped zone 109₁ of the ESD protection layer 109 is electrically coupled to the overlying source metal 108 through a second plurality of vias 111₂ formed in the ILD layer 111. One having ordinary skill in the art should understand that the term “plurality of” herein is not exclusively limited to more than one, but is intended to include one. For instance, in one embodiment, the first plurality of vias 111₁ includes more than one relatively small vias that are arranged to occupy the entire portion of the ILD layer 109 directly overlying the central doped zone 109₁, as illustrated in FIG. 1. In another embodiment, the first plurality of vias 111₁ includes one large via that occupies the entire portion of the ILD layer 109 directly overlying the central doped zone 109₁.

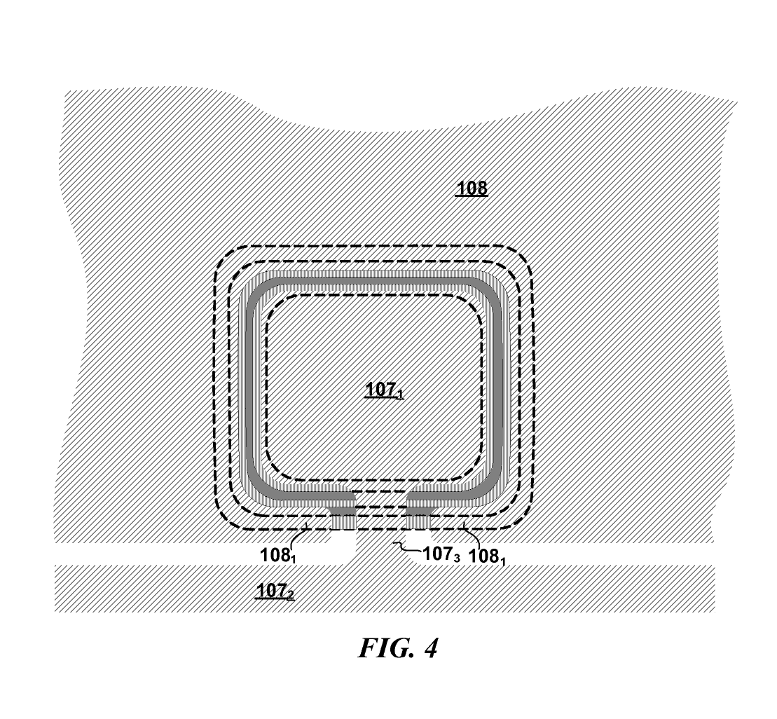

FIG. 4 illustrates a partial enlarged top plan view of an area near the gate metal pad 107₁ corresponding to the top plan view of FIG. 2 in accordance with an exemplary embodiment of the present invention. According to the exemplary embodiment of FIG. 4, the gate metal pad 107₁ is reentrant into the source metal 108 and is substantially enclosed/surrounded by the source metal 108, a gate metal neck 107₃ is formed between the gate metal pad 107₁ and the gate metal runner 107₂ to connect the gate metal pad 107₁ substantially surrounded by the source metal 108 to the gate metal runner 107₂ around outside of the source metal 108. Correspondingly, the source metal 108 has a first source metal finger and a second source metal finger (both labeled as 108₁) respectively formed near both sides of the gate metal neck 107₃ and extending towards the gate metal neck 107₃ to approach the gate metal neck 107₃ so as to substantially enclose the gate metal pad 107₁. In this embodiment, the first and second source fingers 108₁ can also be connected to the outermost first-conductivity-type doped zone 109₁ by vias 111₂. Thus, the series resistance of the ESD protection structure 102 and the metal/polysilicon contacting resistance between the source metal 108 and the ESD protection layer 109 may be further reduced, thereby improving the current uniformity of the ESD protection structure 102.

Although the present disclosure takes the example of an N-channel vertical semiconductor device 100 comprising the N-channel vertical MOSFET 101 and the ESD protection structure 102 to illustrate and explain the structures of a semiconductor device having an ESD protection structure according to various embodiments of the present invention, this is not intended to be limiting. Persons of skill in the art will understand that the structures and principles taught herein also apply to other types of semiconductor materials and devices as well, for example, the device 100 may be a P-channel semiconductor device. In other alternative embodiments, the semiconductor transistor 101 may be a DMOS transistor, a BJT etc. The semiconductor transistor 101 is not limited to vertical transistor and trenched gate transistor described, but can be a lateral transistor or a planar gate transistor instead.

The advantages of the various embodiments of the bootstrap refresh control circuit 103 and the power converter (e.g. 100 or 200) comprising the same of the present invention are not confined to those described above. These and other advantages of the various embodiments of the present invention will become more apparent upon reading the whole detailed descriptions and studying the various figures of the drawings.

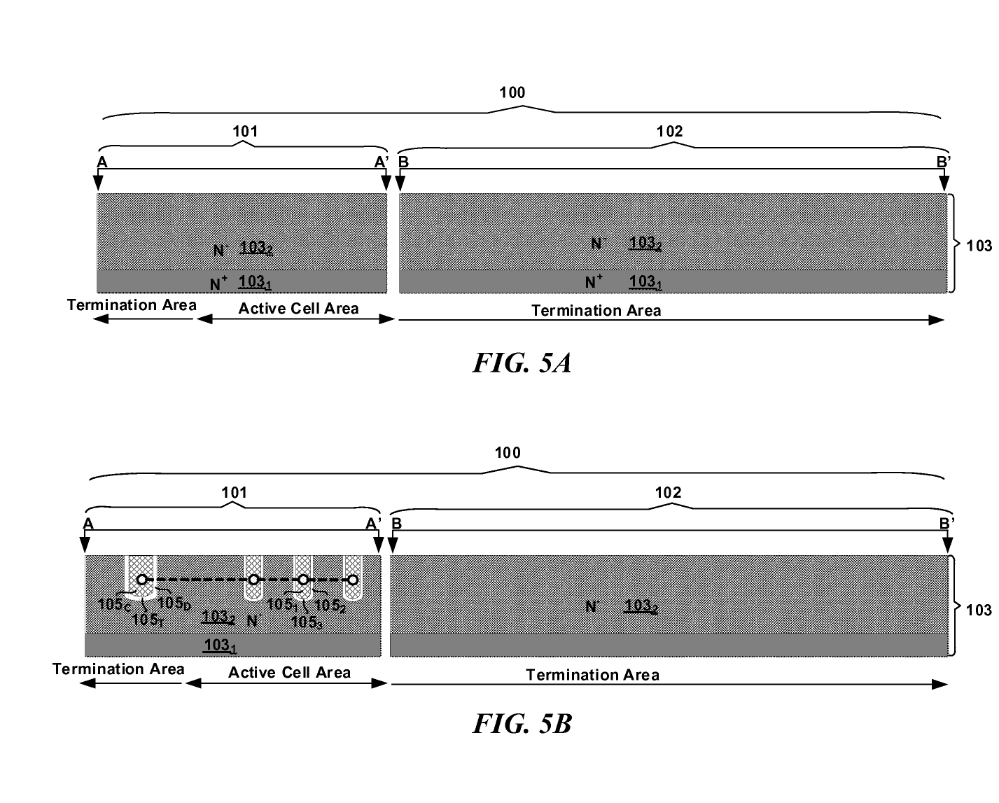

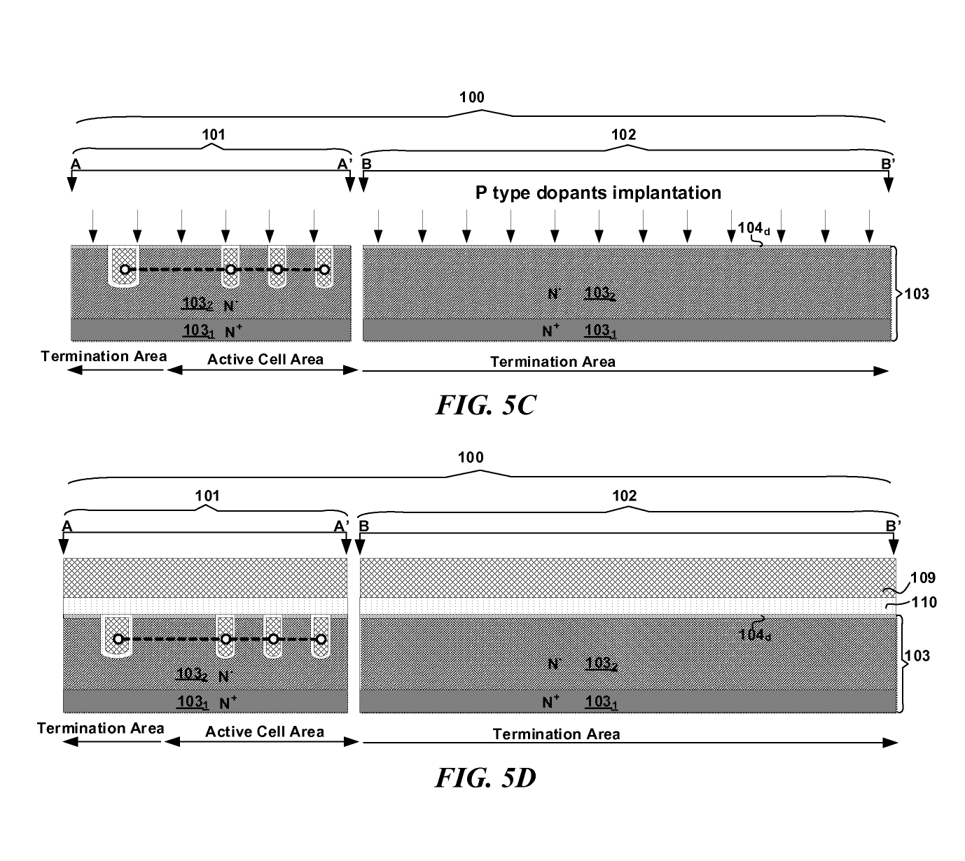

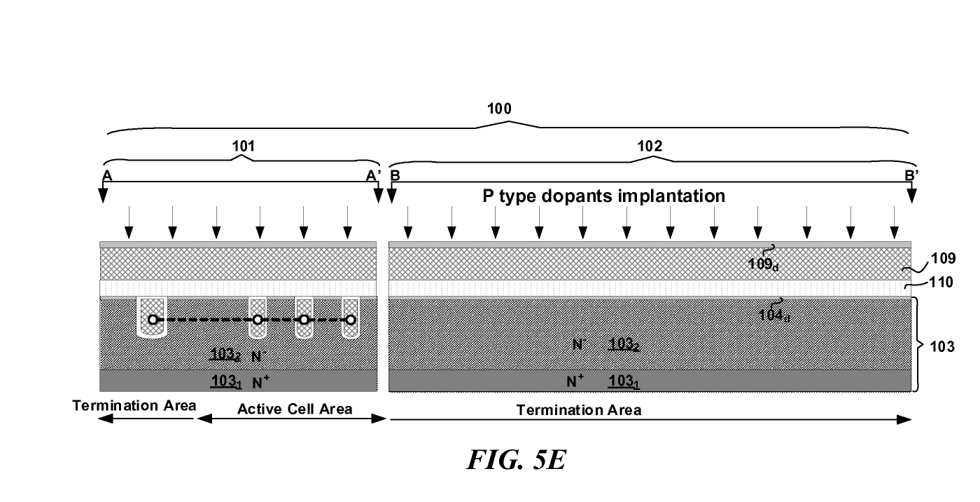

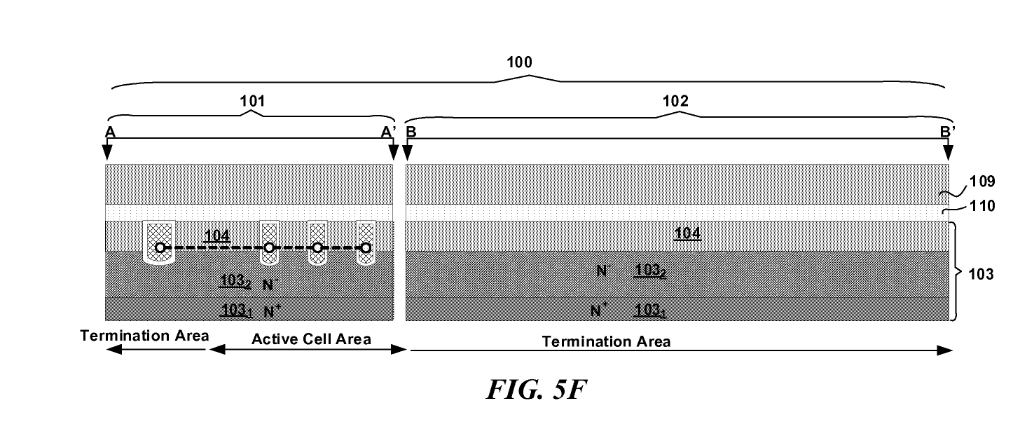

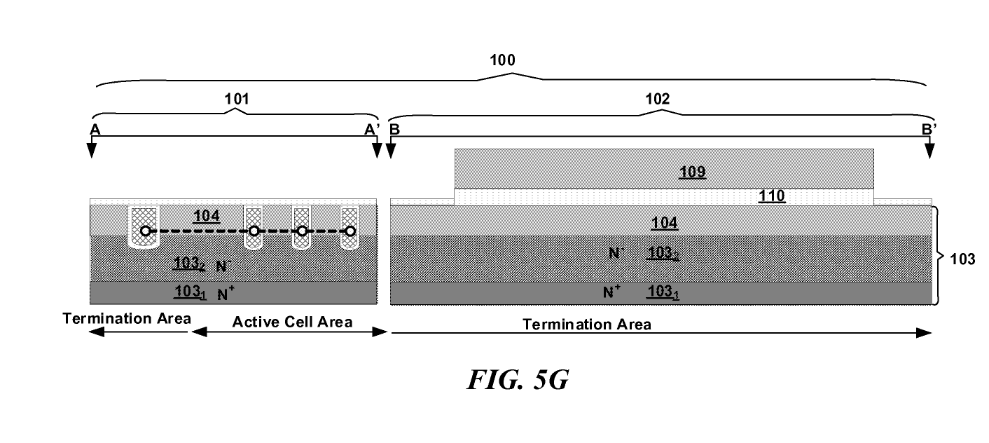

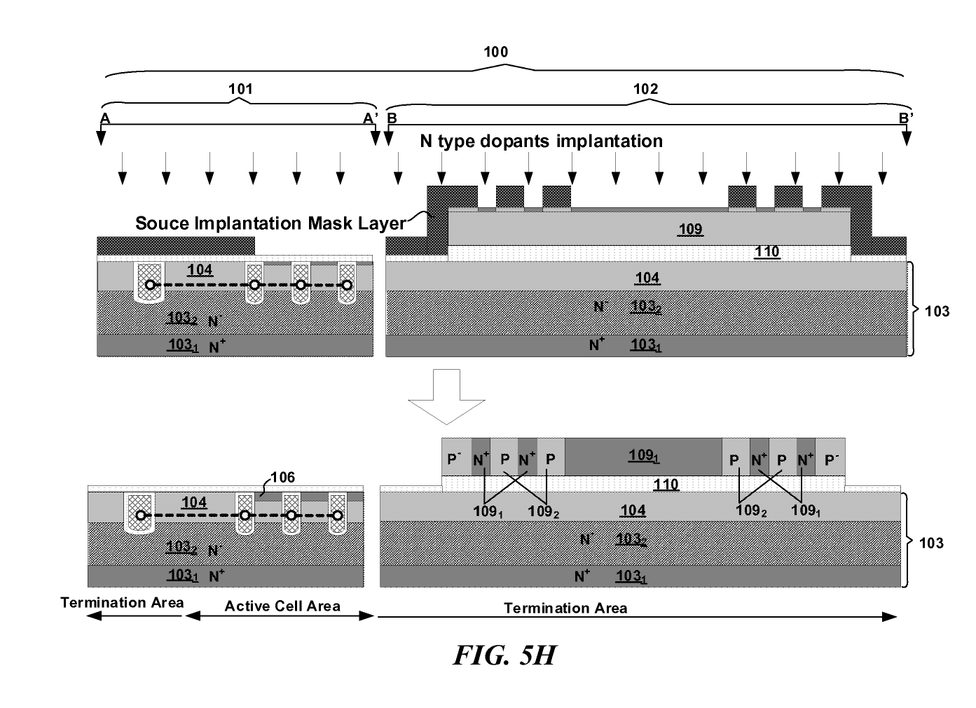

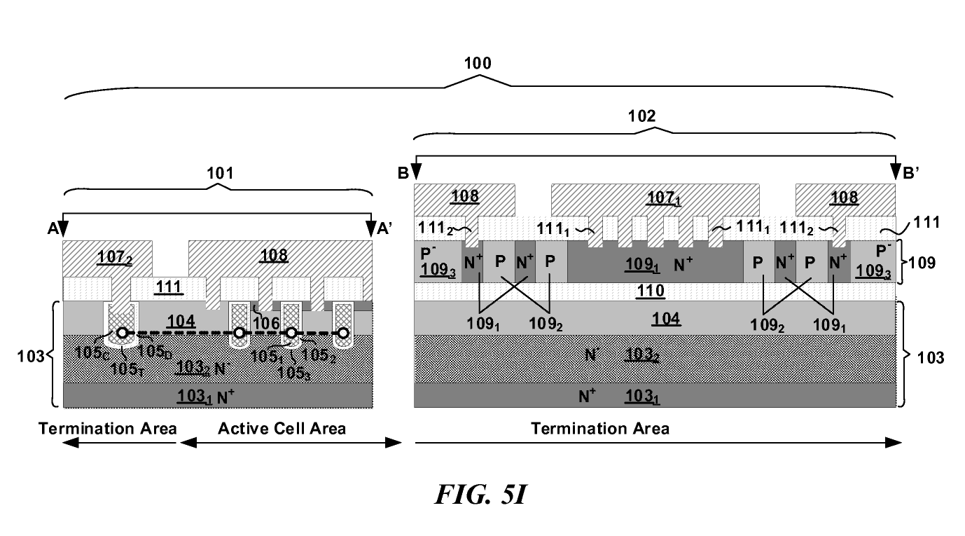

FIGS. 5A through 5I are cross-sectional views illustrating schematically a sequential process of a method for forming a semiconductor device (e.g. the semiconductor device 100) having an ESD protection structure (e.g. the ESD protection structure 102) in accordance with an embodiment of the present invention.

Referring to FIG. 5A, a semiconductor substrate 103 having a first conductivity type (e.g. illustrated as N type in FIG. 5A) is provided. The substrate 103 may comprise a relatively heavy doped substrate layer 103₁ (e.g. illustrated as an N⁺ substrate layer in FIG. 5A) and a relatively light doped epitaxial layer 103₂ (e.g. illustrated as an N⁻ epitaxial layer in FIG. 5A) formed on the substrate layer 103₁. The substrate 103 may be divided into an active cell area and a termination area (also referring to the top plan view illustration in FIG. 2) that are respectively designated for forming active cells of a semiconductor transistor 101 and the ESD protection structure 102. It should be understood that the cross sectional views in FIGS. 5A-5I illustrate only portions of the semiconductor device 100. For instance, the left side sectional view and the right side sectional view in each of these figures respectively illustrate a portion of the active cell area and a portion of the termination area, and can be considered as respectively corresponding to the portions cut from the cut lines AA′ and BB′ in FIG. 2 for better understanding.

Subsequently, referring to FIG. 5B, a gate region 105 (which is intended to include “a plurality of gate regions”) of the semiconductor transistor 101 is formed in the active cell area. In accordance with an exemplary embodiment of the present invention, the gate region 105 may comprise trenched gate region having a trenched gate 105₁ lined with a gate dielectric layer 105₂. Forming the gate region 105 may comprise: forming a gate trench (which is intended to include “a plurality of gate trenches”) 105₃ having sidewalls and a bottom; forming the gate dielectric layer 105₂ lining the sidewalls and bottom of the gate trench 105₃; and filling the lined gate trench 105₃ with a gate conduction layer to form the trenched gate 105₁. In one embodiment, the gate dielectric layer 105₂ may comprise silicon dioxide, the gate conduction layer/the trenched gate 105₁ may comprise doped polysilicon. In accordance with an exemplary embodiment of the present invention, except forming the gate region 105, a trenched gate contact (which is intended to include “a plurality of trenched gate contacts”) is also formed in the termination area of the semiconductor substrate 103. The trenched gate contact may comprise a trenched contact conduction layer 105_{C} lined with a contact dielectric layer 105_{D}. In one embodiment, the trenched gate contact is formed at the same time/with the same processes as forming the trenched gate region 105. For instance, forming the trenched gate contact may comprise: forming a contact trench 105_{T} (which is intended to include “a plurality of contact trenches”) having sidewalls and a bottom; forming a contact dielectric layer 105_{D} lining the sidewalls and bottom of the contact trench 105_{T}; and filling the lined contact trench 105_{T} with a contact conduction layer 105_{C}. In one embodiment, the contact trench/the plurality of contact trenches 105_{T} and the gate trench/the plurality of gate trenches 105₃ are formed in a same step. In one embodiment, the contact dielectric layer 105_{D} and the gate dielectric layer 105₂ may comprise a same dielectric material (e.g. silicon dioxide) and may be formed in a same step (e.g. through thermal oxidation). In one embodiment, the contact conduction layer 105_{C} and the gate conduction layer/the trenched gate 105₁ may comprise a same conduction material (e.g. polysilicon) and may be formed in a same step (e.g. through polysilicon deposition). In accordance with an exemplary embodiment of the present invention, a trenched transverse connection (which is intended to include “a plurality of trenched transverse connections”) connecting the gate trenches 105₃ to the gate contact trenches 105_{T} is also formed in the semiconductor substrate 103, the trenched transverse connection may include transverse segment (illustrated in FIG. 5B by dotted line) of either the gate trenches 105₃ or the gate contact trenches 105_{T} such that the trenched gate 105₁ are connected to the contact conduction layer 105_{C}.

Subsequently, referring to FIG. 5C, a body implantation layer 104_{d} having a second conductivity type (e.g. illustrated as P type in FIG. 5C) opposite to the first conductivity type is formed near the top surface of the semiconductor substrate 103 through second conductivity type dopant implantation from the top surface of the substrate 103. Those having ordinary skill in the art can understand that the body implantation has quite small negligible influence to the gate regions 105. During body dopant implantation, diffusing and other processes, the top surface of the trenched gates 105₁ and the trenched contact conduction layer 105_{C} may be oxidized and a thin oxidation layer (as illustrated in FIG. 5C) may be formed at the top surface of each of the trenched gates 105₁ and the trenched contact conduction layer 105_{C}. Practically, the top surface of the semiconductor substrate 103 may also be oxidized during dopant implantation, diffusing and other processes resulting in a thin oxidation layer (not shown in FIG. 5C for simplicity) formed on the top surface of the substrate 103.

Subsequently, referring to FIG. 5D, a first insulation layer 110 is formed atop the semiconductor substrate 103 and an ESD polysilicon layer 109 is subsequently formed atop the first insulation layer 110. In one embodiment, the first insulation layer 110 is formed through thermal oxidation using a single processing chamber. In other embodiment, the first insulation layer 110 may also be formed with a deposited silicon dioxide layer, nitride layer, a composite oxide or nitride oxide or any other material suitable for use as an electrical isolation layer, or with thermal oxidation in combination with insulation material deposition. In one embodiment, the ESD polysilicon layer 109 may be formed with polysilicon deposition.

Subsequently, referring to FIG. 5E, an ESD implantation layer 109_{d} having the second conductivity type (e.g. illustrated as P type in FIG. 5E) is formed near the top surface of the ESD polysilicon layer 109 through second conductivity type dopant implantation from the top surface of the ESD polysilicon layer 109.

Subsequently, referring to FIG. 5F, a diffusing process is applied so that the body implantation layer 104_{d} is substantially evenly diffused to a desired depth in the substrate 103 to form a body region 104, and the ESD implantation layer 109_{d} is substantially evenly diffused to the entire ESD protection layer 109 so that the ESD protection layer 109 have the second conductivity type.

Now referring to FIG. 5G, a patterned ESD mask layer is applied to cover a portion of the ESD protection layer 109 that is designated for forming the ESD protection structure 102, and in subsequence, the exposed portion of the ESD protection layer 109 that is uncovered by the patterned ESD mask layer and the first isolation layer 110 underlying the exposed portion of the ESD protection layer 109 are removed. In the following the patterned ESD mask layer is removed, thereby leaving a remained portion of the ESD protection layer 109 that was covered by the patterned ESD mask layer and a remained portion of the first insulation layer 110 that is underlying the remained portion of the ESD protection layer 109 atop the termination area of the substrate 103. In one embodiment, the remained portion of the ESD protection layer 109 and the underlying remained portion of the first isolation 110 are of solid closed shape.

Now referring to FIG. 5H, a patterned source implantation mask layer is applied on the remained portion of the ESD protection layer 109 and the substrate 103 to expose surface areas from which dopants of the first conductivity type need to be implanted so as to form a plurality of first-conductivity-type doped zones 109₁ in the ESD protection layer 109 and form source regions 106 in the active cell area. One of ordinary skill in the art should understand that after the dopants implantation, a diffusing process and a step for removing the patterned source implantation mask layer may be proceeded in the following. The source implantation mask layer may have a designed pattern so that after the implantation process of FIG. 5H, the ESD protection layer 109 contains a plurality of first-conductivity type doped zones 109₁ (e.g. illustrated in FIG. 5H as N⁺ type doped zones) interleaving with a plurality of second-conductivity type doped zones 109₂ (e.g. illustrated in FIG. 5H as P type doped zones), wherein the first-conductivity type doped zones 109₁ and second-conductivity type doped zones 109₂ are arranged alternately from an inner side toward an outer side of the ESD protection layer, and in the meanwhile, the source regions 106 are laterally located on both sides of the gate region 105 in the body region 104. For instance, in one embodiment, the patterned source implantation mask layer may include a plurality of mask rings having contour shapes the same as the contour shape of the ESD protection layer 109, wherein the plurality of mask rings are arranged from the inner side toward the outer side of the ESD protection layer 109. In this example, after the implantation process of FIG. 5H, the ESD protection layer 109 contains a first-conductivity type central doped zone 109₁ (e.g. illustrated in FIG. 5H as a central doped zone of N⁺ type) located in a central portion of the ESD protection layer 109, and a plurality of alternately disposed second-conductivity type doped zones 109₂ and first first-conductivity-type doped zones 109₁ surrounding the central doped zone 109₁.

Now referring to FIG. 5I, a second insulation layer 111 (an ILD layer) is formed atop the ESD protection layer 109 and the substrate 103, and a first via 111₁ (which is intended to include “a first plurality of vias” 111₁) and a second via 111₂ (which is intended to include “a second plurality of vias” 111₂) are formed in the second insulation layer 111. The first via/the first plurality of vias 111₁ are located in a portion of the second insulation layer 111, which portion is directly over the central doped zone 109₁. The second via/the second plurality of vias 111₂ are located in a portion of the second insulation layer 111, which portion is directly over the outmost first-conductivity-type doped zone 109₁. In the following, a gate metal 107 and a source metal 108 are formed respectively over the termination area and the active cell area atop the second insulation layer 111, wherein the gate metal 107 and the source metal 108 are separated with a gap. The gate metal 107 is formed to include a gate metal pad 107₁ and a gate metal runner 107₂ (also referring to the top plan view of FIG. 2), wherein the gate metal pad 107₁ is directly over the central doped zone 109₁ and substantially overlies the entirety of the central doped zone 109₁. That is to say, the central portion of the ESD protection layer 109 holding the central doped zone 109₁ refers substantially to the entire portion that is overlapped by the gate metal pad 107₁. The gate metal pad 107₁ is electrically coupled to the central doped zone 109₁ through the first via/the first plurality of vias 111₁, the source metal 108 is electrically coupled to the outermost first-conductivity-type doped zone 109₁ through the second via/the second plurality of vias 111₂.

In accordance with an exemplary embodiment of the present invention, referring back to FIG. 5H, the designed pattern of the patterned source implantation mask layer may be modified so that after the first-conductivity-type dopants implantation, the ESD protection layer 109 further includes a second-conductivity-type floating doped zone 109₃ surrounding and next to the outermost first-conductivity-type doped zone 109₁ that is not intended to couple any established potential and thus is electrically floating and has a floating potential.

In accordance with an exemplary embodiment of the present invention, referring back to FIG. 5I, in the step of forming the gate metal 107 and the source metal 108 further includes patterning the gate metal 107 so that the gate metal pad 107₁ is reentrant into and substantially enclosed/surrounded by the source metal 108, the gate metal runner 107₂ is surrounding outside of the source metal 108, and a gate metal neck 107₃ connecting the gate metal pad 107₁ to the gate metal runner 107₂ is formed; and patterning the source metal 108 so that a first source metal finger and a second source metal finger (both labeled as 108₁) are respectively formed near/at both sides of the gate metal neck 107₃ to approach the gate metal neck 107₃ so as to enclose the gate metal pad 107₁ (also referring to the top plan view of FIG. 4).

Methods and processes/steps of forming the semiconductor device the semiconductor device 100 having the ESD protection structure 102 described above with reference to FIGS. 5A to 5I according to the various embodiments of the present invention are illustrative and not intended to be limiting. Well known manufacturing steps, processes, materials and dopants etc. are not described in detail to avoid obscuring aspects of the technology. Those skilled in the art should understand that the processes/steps described in the embodiments shown may be implemented in different orders and are not limited to the embodiments described. Various modifications to the processes/steps described above are possible.

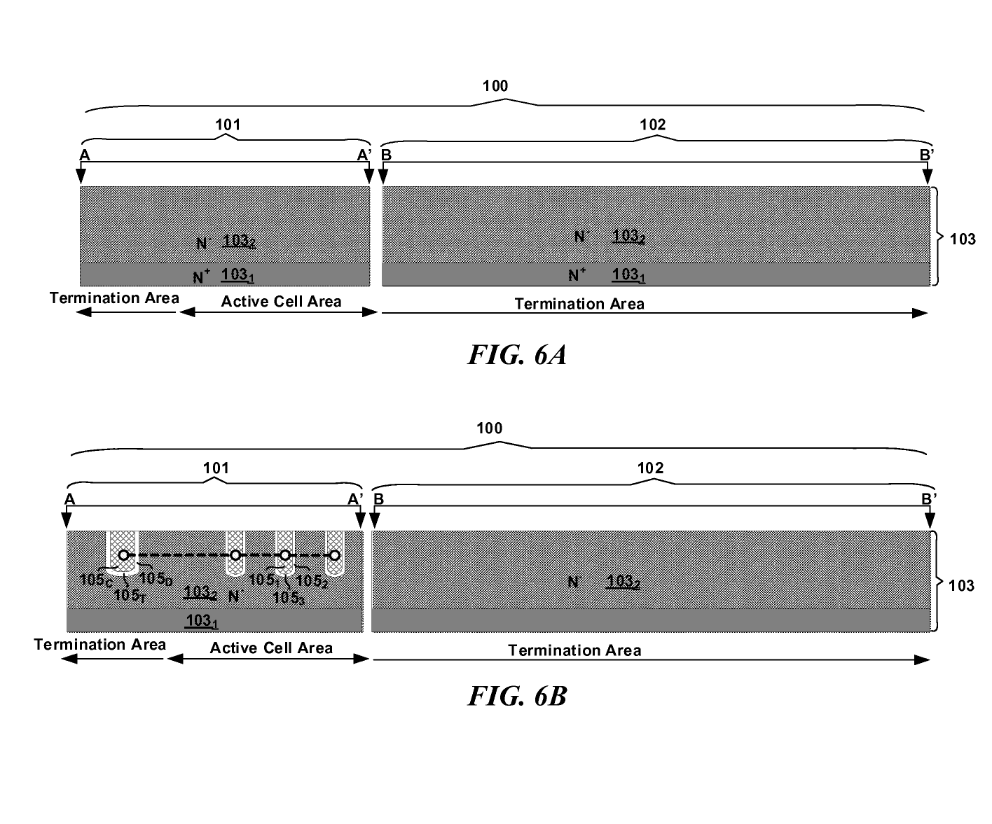

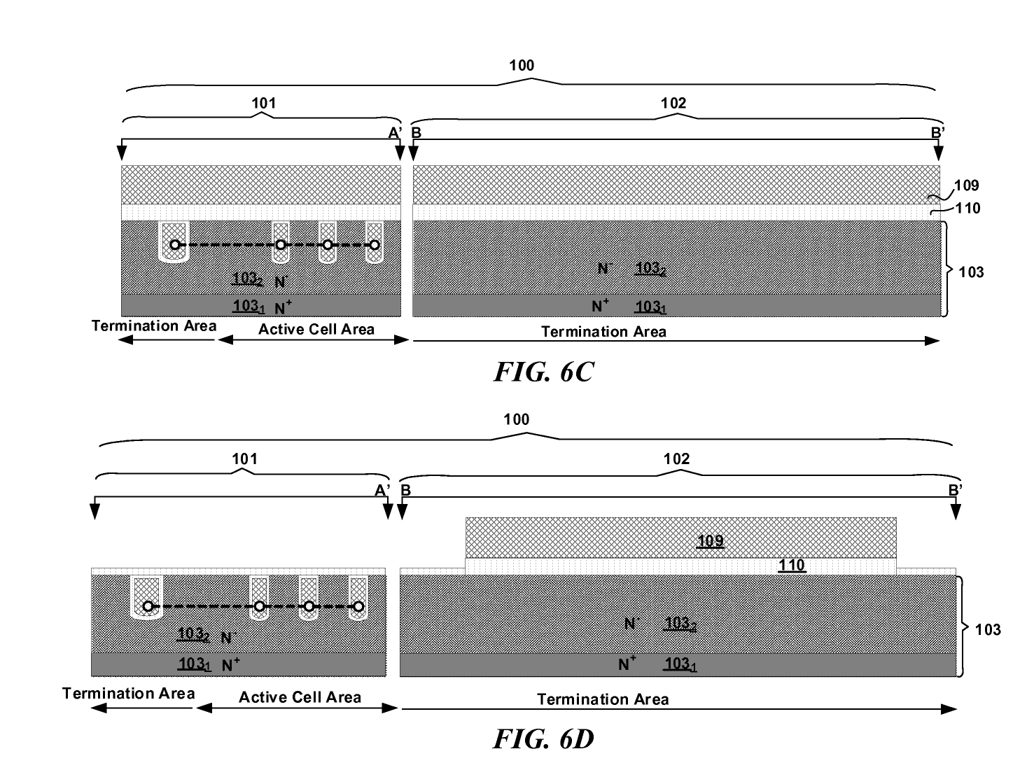

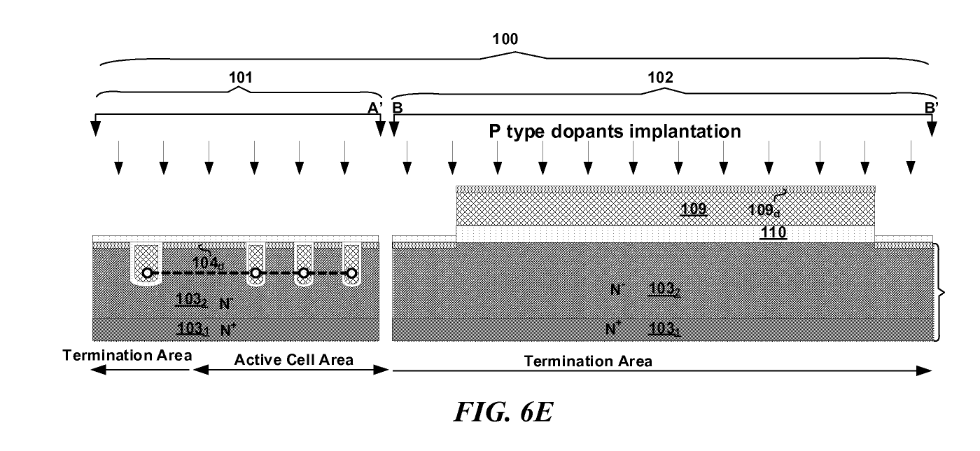

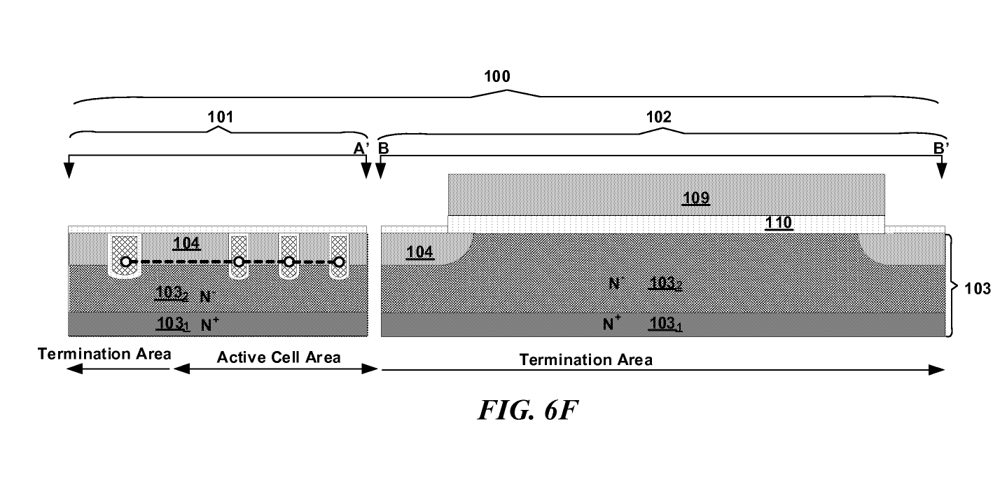

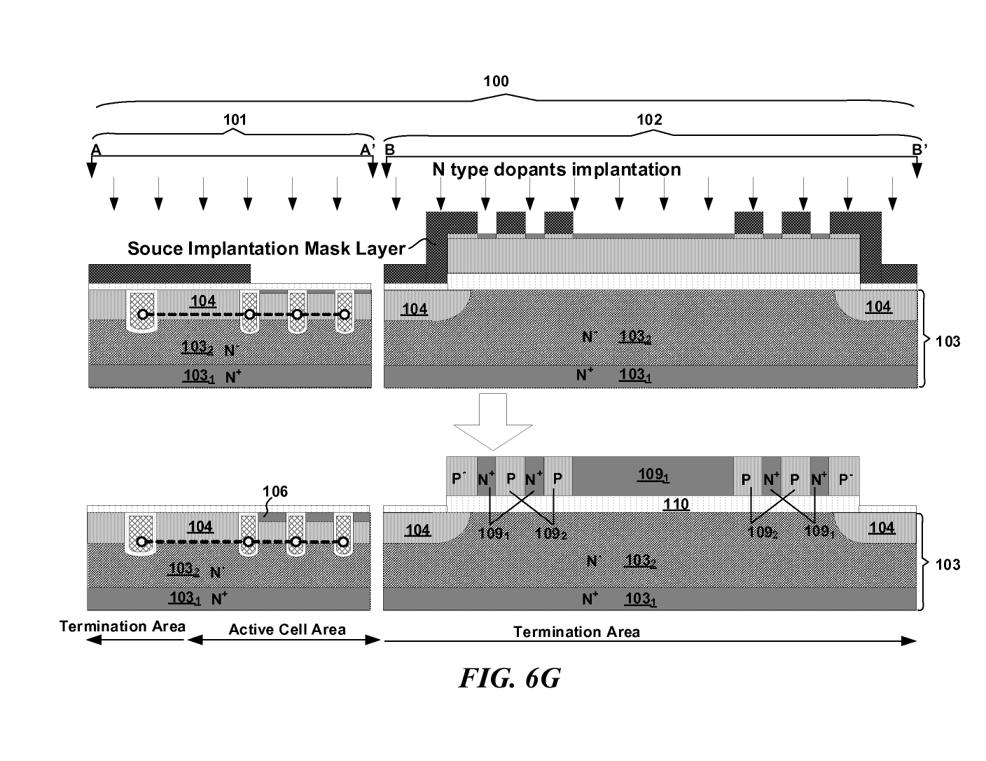

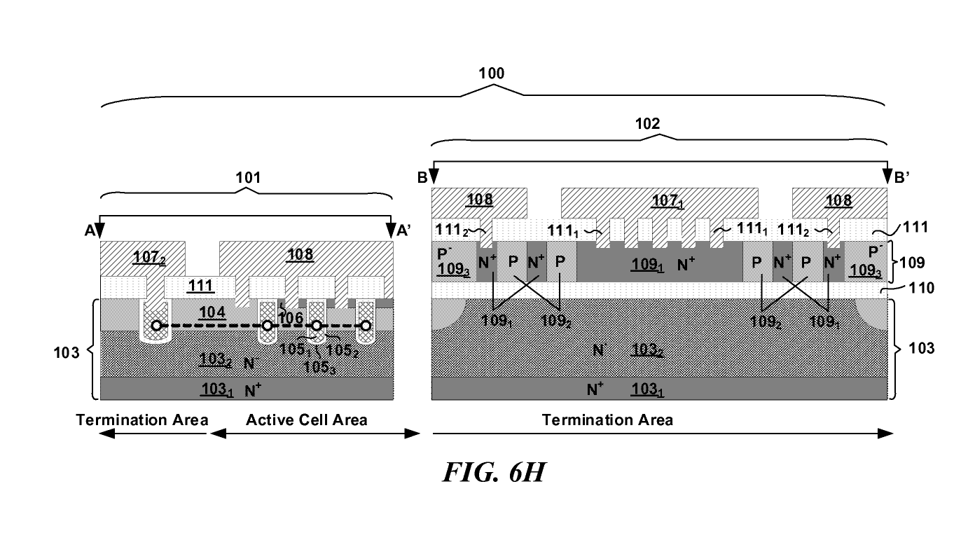

For instance, FIGS. 6A-6H are cross-sectional views illustrating schematically a sequential process of a method for forming a semiconductor device (e.g. the semiconductor device 100) having an ESD protection structure (e.g. the ESD protection structure 102) in accordance with an alternative embodiment of the present invention. The exemplary embodiment illustrated in FIGS. 6A-6H is an alternative to the embodiment described above with reference to FIGS. 5A-5I. In accordance with the exemplary embodiment illustrated in FIGS. 6A-6H, after the processes illustrated and described with reference to FIGS. 5A and 5B (referring to FIGS. 6A and 6B in the present embodiment), the process of body implantation illustrated in FIG. 5C may be omitted, and the processes of forming the first insulation layer 110 and the ESD polysilicon layer 109 illustrated in FIG. 5D are subsequently proceeded (referring to FIG. 6C in the present embodiment). Accordingly, the processes described with reference to FIGS. 5E to 5I are modified as follows: subsequent to the processes of FIG. 5D, the processes illustrated and described with reference to FIG. 5G is proceeded to form the closed shaped first insulation layer 110 and the ESD protection layer 109 (referring to FIG. 6D in the present embodiment); subsequently, the processes illustrated and described with reference to FIGS. 5E and 5F are sequentially proceeded (referring to FIGS. 6E and 6F in the present embodiment); and subsequently, the processes illustrated and described with reference to FIGS. 5H and 5I are sequentially proceeded (referring to FIGS. 6G and 6H in the present embodiment). In the present alternative embodiment, the processes of ESD implantation illustrated in FIG. 6E (described in detail with reference to FIG. 5E) is proceeded after the closed shape first insulation layer 110 and the ESD protection layer 109 are formed as illustrated in FIG. 6D, therefore, the second-conductivity-type dopants for forming the ESD implantation layer 109_{d} are also implanted into exposed portions of the substrate 103 that are uncovered by the closed shape first insulation layer 110 and the ESD protection layer 109. In consequence, after the diffusing processes illustrated in FIG. 6F (described in detail with reference to FIG. 5F), the body region 104 of the second conductivity type is formed in the substrate 103 in the meanwhile when the closed shape ESD protection layer 109 is substantially evenly doped to have the second conductivity type. Therefore, in the present exemplary embodiment illustrated in FIGS. 6A to 6H, the manufacturing processes are simplified without proceeding independent body implantation processes, thereby reducing the manufacturing cost.

Although methods and processes of forming a semiconductor device having an ESD protection structure are illustrated and explained based on forming the semiconductor device 100 comprising an N-channel MOSFET 101 and an ESD protection structure 102 on the semiconductor substrate 103 of N type, this is not intended to be limiting, and persons of ordinary skill in the art will understand that the methods, processes, structures and principles taught herein may apply to any other fabrication processes for forming semiconductor devices having the ESD protection structure disclosed in various embodiments of the present invention.

From the foregoing, it will be appreciated that specific embodiments of the present invention have been described herein for purposes of illustration, but that various modifications may be made without deviating from the spirit and scope of various embodiments of the present invention. Many of the elements of one embodiment may be combined with other embodiments in addition to or in lieu of the elements of the other embodiments. Accordingly, the present invention is not limited except as by the appended claims.

I/We claim:

1. A semiconductor device comprising:
a semiconductor substrate of a first conductivity type and having an active cell area and a termination area;
a semiconductor transistor, formed in the active cell area and having a drain region, a gate region, and a source region;
a source metal, formed over the active cell area of the substrate and electrically coupled to the source region;
a gate metal, formed over the termination area of the substrate and electrically coupled to the gate region, wherein the gate metal includes a gate metal pad and a gate metal runner, and wherein the gate metal is formed around outside of the source metal and is separated from the source metal with a gap; and
an ESD protection structure, formed atop the termination area of the semiconductor substrate and comprising a first insulation layer and an ESD protection layer, wherein the first insulation layer is disposed between the ESD protection layer and the substrate to isolate the ESD protection layer from the substrate; and wherein
the ESD protection layer has a solid closed shape and includes a central doped zone of the first conductivity type located in a central portion of the ESD protection layer, and a plurality of second-conductivity-type doped zones and first-conductivity-type doped zones arranged alternately surrounding the central doped zone towards an outer portion of the ESD protection layer, wherein the second conductivity type is opposite to the first conductivity type, and wherein the central doped zone is located underneath the gate metal pad and occupies substantially the entire central portion of the ESD protection layer that is overlapped by the gate metal pad, and wherein the central doped zone is electrically coupled to the gate metal pad and the outmost first-conductivity-type doped zone among the plurality of second-conductivity-type doped zones and first-conductivity-type doped zones is electrically coupled to the source metal.

2. The semiconductor device of claim 1, wherein
the ESD protection layer further includes a floating doped zone having the second conductivity type and formed surrounding and next to the outermost first-conductivity-type doped zone, wherein the floating doped zone is electrically floating and has a floating potential.

3. The semiconductor device of claim 1, wherein
the gate metal pad is reentrant into the source metal and is substantially enclosed by the source metal; and wherein
the gate metal further has a gate metal neck is formed between the gate metal pad and the gate metal runner to connect the gate metal pad to the gate metal runner; and wherein
the source metal has a first source metal finger and a second source metal finger respectively formed near both sides of the gate metal neck and extending towards the gate metal neck so as to substantially enclose the gate metal pad.

4. The semiconductor device of claim 1, wherein the central doped zone and the plurality of first-conductivity-type doped zones have a relatively heavier dopant concentration than the plurality of second-conductivity-type doped zones.

5. The semiconductor device of claim 2, wherein the floating doped zone has a same dopant concentration as the plurality of second-conductivity-type doped zones.

6. The semiconductor device of claim 2, wherein the floating doped zone has a lighter dopant concentration than the plurality of second-conductivity-type doped zones.

7. The semiconductor device of claim 1, further comprising:
an interlayer dielectric layer formed atop the ESD protection layer and the substrate to separate the source metal and the gate metal from the ESD protection layer and the substrate;
a first plurality of vias formed in a portion of the interlayer dielectric layer directly overlying the central doped zone to electrically couple the central doped zone to the overlying gate metal pad; and
a second plurality of vias formed in a portion of the interlayer dielectric layer directly overlying the outermost first-conductivity-type doped zone to electrically couple the outermost first-conductivity-type doped zone to the overlying source metal.

8. The semiconductor device of claim 1, wherein the semiconductor transistor comprises a vertical trenched gate transistor, and wherein the substrate functions as the drain region.

9. A method for forming a semiconductor device having a semiconductor transistor and an ESD protection structure, comprising:
providing a semiconductor substrate having a first conductivity type, wherein the substrate includes an active cell area and a termination area that are respectively designated for forming active cells of the semiconductor transistor and the ESD protection structure;
forming the semiconductor transistor in the active cell area, wherein forming the semiconductor transistor comprises forming a drain region, a gate region and a source region;
forming the ESD protection structure atop a top surface of the substrate over the termination area, wherein forming the ESD protection structure comprises:
forming a first insulation layer atop the top surface of the substrate over the termination area; forming an ESD protection layer of a solid closed shape atop the first insulation layer; and doping the ESD protection layer so that the ESD protection layer includes a central doped zone of the first conductivity type and a plurality of second-conductivity-type doped zones and first-conductivity-type doped zones alternately arranged surrounding the central doped zone towards an outer portion of the ESD protection layer wherein the second conductivity type is opposite to the first conductivity type;
forming a source metal over the active cell area of the substrate;
forming a gate metal over the termination area of the substrate around outside of the source metal and separated from the source metal with a gap, wherein the gate metal includes a gate metal pad and a gate metal runner; and wherein the gate metal pad is directly over the central doped zone of the ESD protection layer and the central doped zone occupies substantially the entirety of the portion of the ESD protection layer overlapped by the gate metal pad; and
coupling the gate metal pad to the central doped zone, and coupling the source metal to the outermost first-conductivity-type doped zone among the plurality of second-conductivity-type doped zones and first-conductivity-type doped zones.

10. The method of claim 9, wherein doping the ESD protection layer further includes forming a floating doped zone of the second conductivity type surrounding and next to the outermost first-conductivity-type doped zone, wherein the floating doped zone is electrically floating and has a floating potential.

11. The method of claim 9, wherein:
forming the gate metal further includes patterning the gate metal so that the gate metal pad is reentrant into and substantially enclosed by the source metal, and a gate metal neck connecting the gate metal pad to the gate metal runner is formed; and wherein
forming the source metal further includes patterning the source metal so that a first source metal finger and a second source metal finger are respectively formed near both sides of the gate metal neck to approach the gate metal neck so as to enclose the gate metal pad.

12. A method for forming a semiconductor device having an ESD protection structure comprising the steps of:
a) providing a semiconductor substrate having a first conductivity type, wherein the substrate includes an active cell area and a termination area that are respectively designated for forming active cells of a semiconductor transistor and the ESD protection structure;
b) forming a gate region in the active cell area;
c) forming a body implantation layer of a second conductivity type near top surface of the substrate, wherein the second conductivity type is opposite to the first conductivity type;
d) forming a first insulation layer atop the substrate;
e) forming an ESD polysilicon layer atop the first insulation layer;
f) forming an ESD implantation layer of the second conductivity type near top surface of the ESD polysilicon layer;
g) diffusing the body implantation layer substantially evenly to a desired depth in the substrate to form a body region, and diffusing the ESD implantation layer substantially evenly to the entire ESD protection layer so that the ESD protection layer have the second conductivity type;
h) patterning the ESD polysilicon layer and the first insulation layer so that a remained portion of the ESD protection layer and an underlying remained portion of the first insulation layer are located atop the termination area of the substrate and are of solid closed shape;
i) doping the substrate and the ESD polysilicon layer with dopants of the first conductivity type under the shield of a patterned source implantation mask layer so that source regions of the first conductivity type are formed and laterally located on both sides of the gate region in the body region, and that the ESD polysilicon layer includes a central doped zone of the first conductivity type and a plurality of second-conductivity-type doped zones and first-conductivity-type doped zones alternately arranged surrounding the central doped zone towards an outer portion of the ESD polysilicon layer; and
j) forming a source metal over the active cell area of the substrate, and forming a gate metal over the termination area of the substrate around outside of the source metal and separated from the source metal with a gap; wherein the gate metal includes a gate metal pad and a gate metal runner; and wherein the gate metal pad is directly over the central doped zone of the ESD polysilicon layer and the central doped zone occupies substantially the entirety of the portion of the ESD polysilicon layer overlapped by the gate metal pad; and wherein the gate metal pad is electrically coupled to the central doped zone, and the source metal is electrically coupled to the outermost first-conductivity-type doped zone among the plurality of second-conductivity-type doped zones and first-conductivity-type doped zones.

13. The method of claim 12, wherein after the second conductivity type dopants implantation in step i), the ESD polysilicon layer further includes a floating doped zone of the second conductivity type surrounding and next to the outermost first-conductivity-type doped zone, wherein the floating doped zone is electrically floating and has a floating potential.

14. The method of claim 12, wherein, in step j)
forming the gate metal further includes patterning the gate metal so that the gate metal pad is reentrant into and substantially enclosed by the source metal, and a gate metal neck connecting the gate metal pad to the gate metal runner is formed; and wherein
forming the source metal further includes patterning the source metal so that a first source metal finger and a second source metal finger are respectively formed near both sides of the gate metal neck to approach the gate metal neck so as to enclose the gate metal pad.

15. The method of claim 12, wherein the step c) of body implantation is omitted, and wherein the step h) is proceeded prior to the step f) so that the body implantation layer is formed in step f) at the same time with forming the ESD implantation layer, wherein the body implantation layer formed in step f) locates in portions of the substrate that are uncovered by the closed shape ESD polysilicon layer and first insulation layer.
